(19) United States
(12) Patent Application Publication
(10) Pub. No.: US 2024/0256725 A1
(43) Pub. Date: Aug. 1, 2024

(54) INFRASTRUCTURE ASSET PRIORITIZATION SOFTWARE TECHNOLOGIES FOR STEEL AND CONCRETE ASSETS

(71) Applicant: B&N Capital Suppliers, LLC, Creve Coeur, MO (US)

(72) Inventors: Chris Kohl MCDONALD, Ballwin, MO (US); Derek Lee GOFF, Friendswood, MO (US); Nicholas A. LAMM, Dardenne Prairie, MO (US)

(73) Assignee: B&N Capital Suppliers, LLC, Creve Coeur, MO (US)

(21) Appl. No.: 18/426,180

(22) Filed: Jan. 29, 2024

Related U.S. Application Data
(60) Provisional application No. 63/482,119, filed on Jan. 30, 2023.

(51) Int. Cl. G06F 30/13

(52) U.S. Cl. CPC G06F 30/13

(57) ABSTRACT

A novel process and software to conduct infrastructure inspections and prioritization on steel and concrete assets. This is done by using asset specific inspection process to include: data collected from inspection check list, data collected from unmanned underwater remote operated vehicles (ROV), data collection from unmanned aerial vehicles (Lidar and Photogrammetry), and data collected from handheld devices. The combination of this data is fed into a software-based matrix of prioritizing an asset type by severity of conditions and visualizing that data geospatially. This technology calculates the percentage of corrosion on the assets, uses measurements on structural or safety aspects of the asset, and creates a three-dimensional (virtual) visualization and geospatial representation of these assets.

### CROSS REFERENCE TO RELATED APPLICATIONS

The present disclosure is related to that disclosed in the U.S. Provisional Application No. 63/482,119, filed Jan. 30, 2023, entitled “Infrastructure Asset Prioritization Software Technologies for Steel and Concrete Assets.” U.S. Provisional Application No. 63/482,119 is assigned to the assignee of the present application. The present invention hereby claims priority under 35 U.S.C. § 119(e) to U.S. Provisional Application No. 63/482,119.

### TECHNICAL FIELD

The present disclosure relates generally to infrastructure inspection and more particularly to infrastructure visualization and failure prediction.

### BACKGROUND

With the aging infrastructure and increased regulations on each particular industry, the development of data collection and analysis of steel and concrete infrastructure has increased. Previously, analyzing the conditions of assets was completed from the perspective of the evaluator and not based on calculated or machined-based analysis of conditions. Additionally, the rehabilitation of that asset was not based on the severity compared to other like assets in similar industries or regulatory conditions. A new machine-based inspection process that collects the proper information, conducts a weighted prioritization, and visualizes infrastructure information on a geospatial and severity-based failure metric was needed.

### BRIEF DESCRIPTION OF THE DRAWINGS

A more complete understanding of the present invention may be derived by referring to the detailed description when considered in connection with the following illustrative figures. In the figures, like reference numbers refer to like elements or acts throughout the figures.

FIG. 1 illustrates an infrastructure inspection network, according to a first embodiment;

FIG. 2 illustrates the infrastructure inspection system of FIG. 1 in greater detail in accordance with an embodiment;

FIG. 3 illustrates a method of infrastructure prioritization and visualization, according to an embodiment;

FIG. 4 illustrates an exemplary infrastructure prioritization matrix, according to an embodiment;

FIG. 5 illustrates a severity and likelihood of failure chart, according to an embodiment;

FIG. 6 illustrates an exemplary geospatial representation, according to an embodiment; and

FIG. 7 illustrates an exemplary geospatial representation, according to a further embodiment.

### DETAILED DESCRIPTION

Aspects and applications of the invention presented herein are described below in the drawings and detailed description of the invention. Unless specifically noted, it is intended that the words and phrases in the specification and the claims be given their plain, ordinary, and accustomed meaning to those of ordinary skill in the applicable arts.

In the following description, and for the purposes of explanation, numerous specific details are set forth in order to provide a thorough understanding of the various aspects of the invention. It will be understood, however, by those skilled in the relevant arts, that the present invention may be practiced without these specific details. In other instances, known structures and devices are shown or discussed more generally in order to avoid obscuring the invention. In many cases, a description of the operation is sufficient to enable one to implement the various forms of the invention, particularly when the operation is to be implemented in software. It should be noted that there are many different and alternative configurations, devices and technologies to which the disclosed inventions may be applied. The full scope of the inventions is not limited to the examples that are described below.

As described below, embodiments of the following disclosure provide a system and method of conducting infrastructure inspections and prioritization on steel and concrete assets. According to one aspect, infrastructure inspections and prioritization comprises asset-specific inspection processes such as, for example, data collected from inspection check list, data collected from unmanned underwater remote operated vehicles (ROV), data collection from unmanned aerial vehicles (Lidar and Photogrammetry), and data collected from handheld devices. An infrastructure prioritization matrix receives this data and prioritizes an asset type by severity of conditions and geospatial visualizing. Embodiments further contemplate determining corrosion on the assets, measurements of structural or safety aspects of the asset, and generating a three-dimensional (virtual) visualization and geospatial representation of the asset.

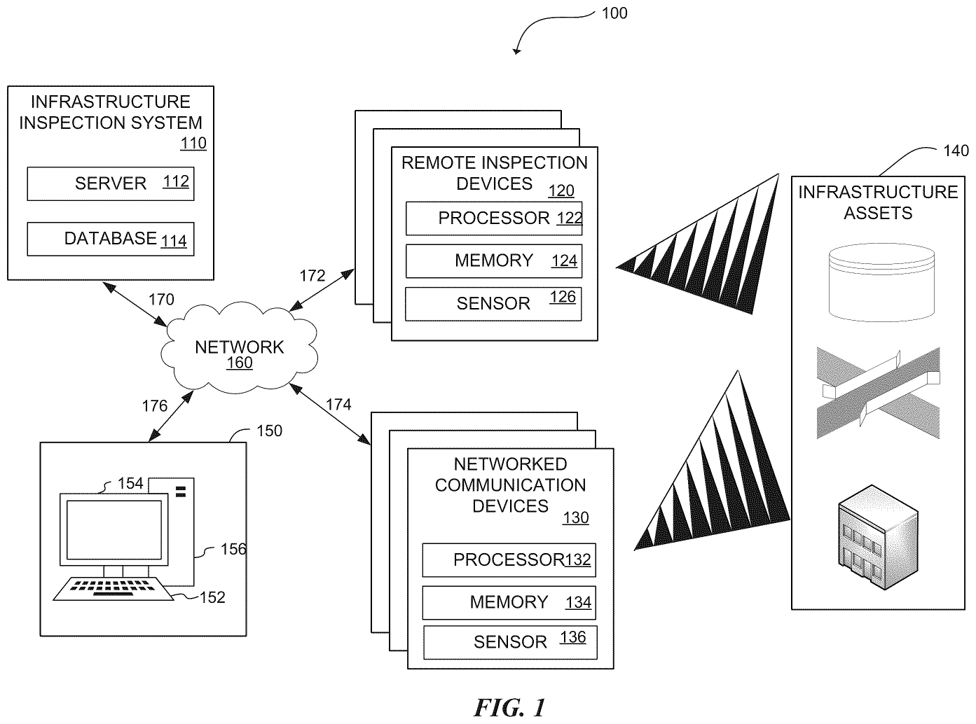

FIG. 1 illustrates an infrastructure inspection network 100, according to a first embodiment. Infrastructure inspection network 100 comprises infrastructure inspection system 110, one or more remote inspection devices 120, one or more networked communication devices 130, one or more infrastructure assets 140, computer 150, network 160, and communication links 170-178. Although a single infrastructure inspection system 110, one or more remote inspection devices 120, one or more networked communication devices 130, one or more infrastructure assets 140, a single computer 150, a single network 160, and one or more communication links 170-178 are shown and described, embodiments contemplate any number of infrastructure inspection systems, remote inspection devices, networked communication devices, infrastructure assets, computers, networks, and communication links, according to particular needs.

In one embodiment, infrastructure inspection system 110 comprises server 112 and database 114. As explained in more detail below, server 112 comprises one or more modules to, for example, provide for the inspection and evaluation of infrastructure assets 140 such as, for example, steel and concrete assets, which may include, but are not limited to: water storage tanks, transmission towers, roadways, bridges, ground storage tanks, manholes, waste water treatment facilities, man holes or ways, and the like. Furthermore, prioritization analysis methods of the infrastructure inspection system 110 comprise determining the likelihood of failure and predicting failure of one or more infrastructure assets 140 using machine learning over time.

One or more remote inspection devices 120 comprise processor 122, memory 124, and sensors 126. According to embodiments, remote inspection devices 120 comprise one or more Remote Operated Vehicles (ROVs) (which may be referred to as “unmanned underwater drones”), unmanned aerial vehicles (such as, for example, a quadcopter, hexacopter, or other fixed or unfixed aerial drone), and other like remotely operated electronic sensing devices. According to embodiments, one or more sensors 126 of one or more remote inspection devices 120 comprise an imaging sensor, such as, a camera, scanner, electronic eye, photodiode, charged coupled device (CCD), ultrasonic emitter and receiver, GPS receiver, Light Detection and Ranging (LiDAR) device, hyperspectral sensor, or any other electronic component that detects physical characteristics (such as color, shape, size, thickness, surface texture, composition, or the like). In one example, sensor 126 comprises ultrasonic sensor for detection and measurement of thickness of a component of one or more infrastructure assets 140, such as, for example, thickness measurement of steel. By way of further example, data from aerial unmanned drones may comprise collection of LiDAR, photogrammetry, and triangulation from GPS data to provide for the collection of total measurements of the assets, measurements of corroded steel or concrete, or failed structural aspects of the asset. LiDAR collection provides for the most accurate calculation of the size of infrastructure assets 140 at sub-inch resolution. In addition, or as an alternative, photogrammetry is overlayed with the LiDAR data to determine the amount of corrosion present on the asset. One or more remote inspection devices 120 may comprise radio, satellite, or other communication systems that communicates location information (such as, for example, geographic coordinates, distance from a location, global positioning satellite (GPS) information, or the like).

One or more networked communication devices 130 comprise one or more processors 132, memory 134, one or more sensors 136, and may include any suitable input device, output device, fixed or removable computer-readable storage media, or the like. According to embodiments, one or more networked communication devices 130 comprise an electronic device that receives imaging data from one or more sensors 136 or from one or more databases in infrastructure inspection network 100. One or more sensors 136 of one or more networked communication devices 130 may comprise an imaging sensor, such as, a camera, scanner, electronic eye, photodiode, charged coupled device (CCD), or any other electronic component that detects physical characteristics of an infrastructure asset 140. One or more networked communication devices 130 may comprise, for example, a mobile handheld electronic device such as, for example, a smartphone, a tablet computer, a wireless communication device, and/or one or more networked electronic devices configured to image infrastructure assets using one or more sensors 136 and transmit images to one or more databases. In addition, or as an alternative, one or more sensors 136 may comprise a radio receiver and/or transmitter configured to read an electronic tag, such as, for example, a radio-frequency identification (RFID) tag. Each infrastructure asset may be represented in infrastructure inspection network 100 by an identifier, including, for example, serial number, barcode, tag, RFID, or like objects that encode identifying information. One or more networked communication devices 130 may generate a mapping of one or more infrastructure assets 140 in infrastructure inspection network 100 by scanning an identifier or object associated with the infrastructure asset 140 and identifying infrastructure asset 140 based, at least in part, on the scan. As explained in more detail below, infrastructure inspection system 110 may use the mapping of infrastructure asset 140 to locate infrastructure asset 140 in infrastructure inspection network 100. The location of infrastructure asset 140 may be used to coordinate the inspection routine of infrastructure asset 140 in infrastructure inspection network 100 according to one or more actions, tasks, plans and/or a rehabilitation priority or schedule of infrastructure asset 140.

As disclosed above, one or more infrastructure assets 140 comprise any type of infrastructure that requires periodic inspection and maintenance, such as, for example, steel and concrete assets, which may include, but are not limited to: water storage tanks, transmission towers, roadways, bridges, ground storage tanks, manholes, waste water treatment facilities, man holes or ways, and the like. Although particular infrastructure assets 140 are shown and described, embodiments contemplate inspection and rehabilitation calculations for any suitable one or more of the same or different types of infrastructure assets 140. In one embodiment, one or more infrastructure assets 140 may comprise all water tanks that are maintained by a particular entity. In other embodiments, one or more infrastructure assets 140 may comprise all bridges in a particular state. In still further embodiments, one or more infrastructure assets 140 may comprise all assets under a particular jurisdiction or regulatory authority, such as, for example, all roadways, bridges, and tunnels in a particular state.

As shown in FIG. 1, infrastructure inspection network 100 operates on one or more computers 150 that are integral to or separate from the hardware and/or software that support infrastructure inspection system 110, one or more remote inspection devices 120, and one or more networked communication devices 130. Infrastructure inspection network 100 comprising infrastructure inspection system 110, one or more remote inspection devices 120, and one or more networked communication devices 130 may operate on one or more computers 150 that are integral to or separate from the hardware and/or software that support infrastructure inspection system 110, one or more remote inspection devices 120, and one or more networked communication devices 130. One or more computers 150 may include any suitable input device 152, such as a keypad, mouse, touch screen, microphone, or other device to input information. One or more computers 150 may also include any suitable output device 154, such as, for example, a computer monitor, that may convey information associated with the operation of infrastructure inspection network 100, including digital or analog data, visual information, or audio information.

Computer 150 may include fixed or removable computer-readable storage media, including a non-transitory computer readable medium, magnetic computer disks, flash drives, CD-ROM, in-memory device or other suitable media to receive output from and provide input to infrastructure inspection network 100. Computer 150 may include one or more processors 156 and associated memory to execute instructions and manipulate information according to the operation of infrastructure inspection network 100 and any of the methods described herein. An apparatus implementing special purpose built logic circuitry, for example, one or more field programmable gate arrays (FPGA) or application-specific integrated circuits (ASIC) may perform functions of the method described herein. One or more processors 156 may execute an operating system program stored in memory to control the overall operation of computer 150. For example, one or more processors 156 control the reception and transmission of signals within the system. One or more processors 156 execute other processes and programs resident in memory, such as, for example, registration, identification or communication and moves data into or out of the memory, as required by an executing process. In addition, or as an alternative, embodiments contemplate executing the instructions on computer 150 that cause computer 150 to perform functions of the method. Further examples may also include articles of manufacture including tangible computer-readable media that have computer-readable instructions encoded thereon, and the instructions may comprise instructions to perform functions of the methods described herein.

In addition, infrastructure inspection network 100 may comprise a cloud-based computing system having processing and storage devices at one or more locations, local to, or remote from infrastructure inspection system 110, one or more remote inspection devices 120, and one or more networked communication devices 130. In addition, each of one or more computers 150 may be a work station, personal computer (PC), network computer, notebook computer, tablet, personal digital assistant (PDA), cell phone, telephone, smartphone, wireless data port, augmented or virtual reality headset, or any other suitable computing device. In an embodiment, one or more users may be associated with infrastructure inspection system 110, one or more remote inspection devices 120, and one or more networked communication devices 130. In addition, or as an alternative, these one or more users within infrastructure inspection network 100 may include, for example, one or more computers 150 programmed to autonomously handle, among other things, one or more activities of the described methods and related tasks within infrastructure inspection network 100.

In one embodiment, each of infrastructure inspection system 110, one or more remote inspection devices 120, one or more networked communication devices 130, and computer 150 may be coupled with network 160 using communication links 170-176, which may be any wireline, wireless, or other link suitable to support data communications between infrastructure inspection system 110 and network 160 during operation of infrastructure inspection network 100. Although communication links 170-176 are shown as generally coupling infrastructure inspection system 110, one or more remote inspection devices 120, and one or more networked communication devices 130, and computer 150 to network 160, any of infrastructure inspection system 110, one or more remote inspection devices 120, and one or more networked communication devices 130, and computer 150 may communicate directly with each other, according to particular needs.

In another embodiment, network 160 includes the Internet and any appropriate local area networks (LANs), metropolitan area networks (MANs), or wide area networks (WANs) coupling infrastructure inspection system 110, one or more remote inspection devices 120, and one or more networked communication devices 130, and computer 150. For example, data may be maintained locally to, or externally of infrastructure inspection system 110, one or more remote inspection devices 120, and one or more networked communication devices 130, and computer 150 and made available to one or more associated users of infrastructure inspection system 110, one or more remote inspection devices 120, and one or more networked communication devices 130, and computer 150 using network 160 or in any other appropriate manner. For example, data may be maintained in a cloud database at one or more locations external to infrastructure inspection system 110, one or more remote inspection devices 120, and one or more networked communication devices 130, and computer 150 and made available to one or more associated users of infrastructure inspection system 110, one or more remote inspection devices 120, and one or more networked communication devices 130, and computer 150 using the cloud or in any other appropriate manner. Those skilled in the art will recognize that the complete structure and operation of network 160 and other components within infrastructure inspection network 100 are not depicted or described. Embodiments may be employed in conjunction with known communications networks and other components.

Computers 150 may also receive, from one or more remote inspection devices 120 and/or one or more networked communication devices 130, a location and evaluation of the identified asset. Based on the scan of the asset, computers 150 may also identify (or alternatively generate) a first mapping in the database system, where the first mapping is associated with the current evaluation of the asset. Computers 150 may also identify a second mapping in the database system, where the second mapping is associated with a past evaluation of the identified asset. Computers 150 may also compare the first mapping and the second mapping to determine if the current status of the identified asset in the first mapping is different than the past status of the identified asset in the second mapping. Computers 150 may then send instructions to one or more remote inspection devices 120 based, as least in part, on one or more differences between the first mapping and the second mapping such as, for example, a change in the physical appearance or stability of one or more infrastructure assets 140.

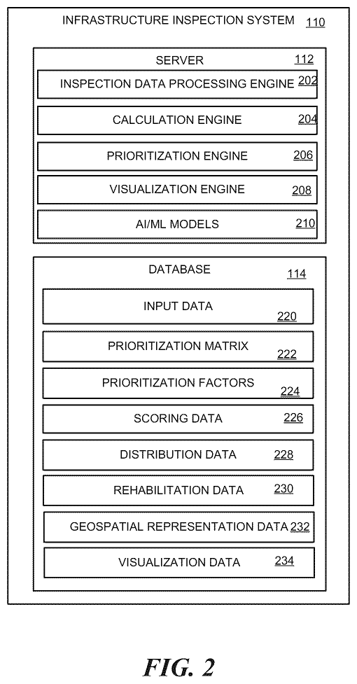

FIG. 2 illustrates infrastructure inspection system 110 of FIG. 1 in greater detail in accordance with an embodiment. As discussed above, infrastructure inspection system 110 may comprise one or more computers 150 at one or more locations including associated input devices 152, output devices 154, non-transitory computer-readable storage media, processors 156, memory, or other components for receiving, processing, storing, and communicating information according to the operation of infrastructure inspection network 100. Additionally, infrastructure inspection system 110 comprises server 112 and database 114. Although infrastructure inspection system 110 is shown as comprising a single server 112 and a single database 114, embodiments contemplate any suitable number of computers 150, servers 112, or databases 114 internal to or externally coupled with infrastructure inspection system 110.

Server 112 of infrastructure inspection system 110 may comprise inspection data processing engine 202, calculation engine 204, prioritization engine 206, visualization engine 208, and AI/ML models 210. Although server 112 is illustrated and described as comprising a single inspection data processing engine 202, a single calculation engine 204, a single prioritization engine 206, a single visualization engine 208, and one or more AI/ML models 210, embodiments contemplate any suitable number or combination of these located at one or more locations, local to, or remote from infrastructure inspection system 110, such as on multiple servers 112 or computers 150 at any location in infrastructure inspection network 100.

According to embodiments, inspection data processing engine 202 receives and processes data input, such as, for example, input data 220. In addition, inspection data processing engine 202 cleans data, formats data into a similar format, and preprocesses data for use by AI/ML models 210. One or more remote inspection devices 120, networked communication devices 130, and/or one or more computers 140 may transmit input to infrastructure inspection system 110 using one or more communication links 170-178. Inspection data processing engine 202 may register the input from one or more remote inspection devices 120, networked communication devices 130, and/or one or more computers 140 and transmit the input to calculation engine 204, prioritization engine 206, and visualization engine 208. Calculation engine 204 generates, accesses, and solves prioritization matrix 222. Inspection data processing engine 202 provides calculation engine 204 with input data 220, and calculation engine 204 generates prioritization matrix 222 with processed input data 220 and utilizing prioritization factors 224 to generate scoring data 226. Prioritization engine 206 determines a rehabilitation priority for each of the assessed infrastructure assets 140 using scoring data 226 to generate distribution data 228. As described in more detail below, prioritization engine 206 uses statistical analysis and/or an AI/ML model 210 to assign a rehabilitation priority to one or more infrastructure assets 140.

Visualization engine 208 generates one or more graphical user interface displays, geospatial representations, and visualizations of one or more infrastructure assets 140. As described in further detail below, visualization engine According to embodiments, visualization engine 208 may access database 114 to generate one or more graphical user interface displays, geospatial representations, and visualizations of one or more infrastructure assets 140, as described in further detail below.

AI/ML Models 210 comprise one or more supervised or unsupervised trained models that receive current and historical inspection data on components, and some subcomponents, particular to certain asset types, such as, for example, a valve on a pipeline. As inspection data processing engine 202 collects this data over time, prioritization engine 206 trains one or more machine learning or AI models to identify trends in failures based on a range of factors (i.e. geographic locations, placement in the system, and the like). In addition or as an alternative, prioritization engine 206 receives as training data the historical probability and weighted scores, which are then used to generate AI/ML models 210. Further, probability and weighted scores are received by calculation engine 204 to refine failure rates calculated by prioritization matrix 222, providing for predicting them with reasonable probability. Through the process of analyzing input data 220 collected by multiple sources, visualization engine 208 provides for manual selection of areas of corrosion on an infrastructure asset. According to embodiments, this provides for measurement of the percentage of the assets that have corroded by overlaying the photogrammetry and LiDAR measurements.

In addition, as inspection occurs over time, three-dimensional change detection of assets may be accomplished by using the photogrammetry and LiDAR data collection to geolocate these assets allowing for virtual ‘walk arounds.’ In addition, as additional data is received over time, visualization engine 208 illustrates the progression of corrosion (or other failures) on specific parts of the assets (change detection) and specific locations, such as, for example, mold growth over time on assets and particularly types of coating systems that allow growth.

Database 114 of infrastructure inspection system 110 may comprise one or more databases or other data storage arrangements at one or more locations, local to, or remote from, server 112. Database 114 may comprise, for example, input data 220, prioritization matrix 222, prioritization factors 224, scoring data 226, distribution data 228, rehabilitation data 230, geospatial representation data 232, and visualization data 234. Although database 114 is shown and described as comprising input data 220, prioritization matrix 222, prioritization factors 224, scoring data 226, distribution data 228, rehabilitation data 230, geospatial representation data 232, and visualization data 234, embodiments contemplate any suitable number or combination of these, located at one or more locations, local to, or remote from, infrastructure inspection system 110 according to particular needs.

According to embodiments, input data 220 comprises infrastructure inspection input from one or more input data sources, such as, for example, ROV inspection data, aerial drone data, interior unsubmerged inspection data, and the like. Prioritization matrix 222 is utilized by calculation engine 204 to calculate scoring data 226 for infrastructure assets 140 based, at least in part, on one or more prioritization factors 224 and input data 220. According to an embodiment, prioritization factors 224 comprise one or more factors used to assess the severity and probability of failure of one or more infrastructure assets 140. Scoring data 226 is generated by calculation engine 204 and comprises weights and scores generated from prioritization matrix 222. As described in further detail below, each type of infrastructure asset 140 comprises a particular quantity of factors to be weighted and scored during the inspection process. However, those factors can be changed or weighed differently based on the infrastructure owners' priorities or the regulatory condition to maintain that infrastructure assets.

Distribution data 228 comprises processed scoring data 226 comprising a bell curve representing the severity and likelihood of failure of the assess infrastructure assets 140. In one embodiment, the rehabilitation priority is determined by analyzing the bell curve representing the inspected infrastructure assets to other like assets scored and generating a probable zone for rehabilitation. According to embodiments, distribution data 1228 comprises historical scoring data which that is used as training data for a machine learning or AI model. Historical scoring data may be stored at time intervals such as, for example, by the minute, hour, daily, weekly, monthly, quarterly, yearly, or any suitable time interval, including substantially in real time. Rehabilitation data 230 comprises the rehabilitation priority assigned to one or more infrastructure assets 140 based, at least in part, on the distribution data 228. Geospatial representation data 232 comprises one or more geospatial representations of the rehabilitation priority, mapping data, and other like visualizations. According to embodiments, visualization data 234 comprises three-dimensional walkaround and metadata associated with one or more filtered and selected data points associated with one or more infrastructure assets 140.

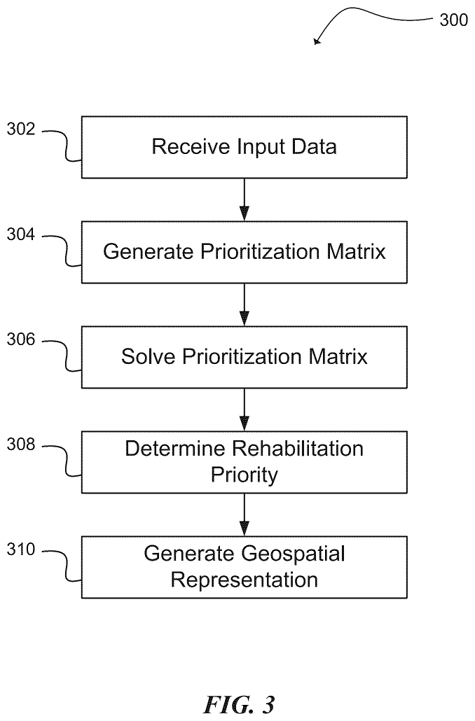

FIG. 3 illustrates method 300 of infrastructure prioritization and visualization, according to an embodiment. The following method 300 proceeds by one or more activities, which although described in a particular order may be performed in one or more permutations, combinations, orders, or repetitions, according to particular needs.

At activity 302, inspection data processing engine 202 receives input data 220 from one or more remote inspection devices 120 and/or one or more networked communication devices 130. In one embodiment, inspection data processing engine 202 receives input data 220 from one or more of the following four components: an inspection checklist to confirm the collection of data needed to prioritize; data collected from remote operated vehicles (ROVs) (such as, for example, unmanned underwater drones for submerged steel or concrete); data collected from one or more unmanned aerial drones to collect imagery (photogrammetry) and Light Detection and Ranging (LiDAR) data; and data collected from imagery and spatial systems for interior areas not submerged. Although embodiments are shown and described as comprising each of the four components, embodiments contemplate other combinations of these or other data sources or components according to particular needs.

At activity 304, calculation engine 204 generates prioritization matrix 222 using one or more prioritization factors 224. In one embodiment, calculation engine 204 receives processed input data 220 from inspection data proceeding engine 202 and generates prioritization matrix 222. Prioritization matrix 222 does not require all of the collected data, only data related to prioritization factors 224, which are utilized to assess the severity and probability of failure. For example, water storage tanks comprise approximately fifty-two prioritization factors 224, while over 585 points of data are collected during inspection.

At activity 306, calculation engine 204 solves prioritization matrix 222 to generate scores for one or more infrastructure assets 140. According to embodiments, each asset type has a particular number of factors that are weighted and scored during solving of prioritization matrix 222. In addition, or as an alternative, prioritization factors 224 are changed or weighed differently based on the infrastructure owners' priorities or the regulatory condition to maintain the infrastructure assets 140.

At activity 308, prioritization engine 206 determines a rehabilitation priority for each of the assessed infrastructure assets 140. In one embodiment, scoring data 226 from the solved prioritization matrix 222 generates distribution data 228 comprising a bell curve representing the severity and likelihood of failure of the assess infrastructure assets 140. In one embodiment, the rehabilitation priority is determined by analyzing the bell curve representing the inspected infrastructure assets to other like assets scored and generating a probable zone for rehabilitation.

At activity 310, visualization engine 208 generates a geospatial representation of the infrastructure assets 140. In embodiment, visualization engine 208 generates geospatial representation data 232 comprising a visualization of the data geospatially using, for example, the location of each asset along with the triangulated GPS overlay of the LiDAR and photogrammetry imaging. In addition, or as an alternative, visualization engine 208 generates a geospatial representation providing for filtering and selection of the displayed infrastructure assets 140, such as, for example, by type of infrastructure assets, industry, or geographic territory.

To further illustrate method 300 of infrastructure prioritization and visualization, an example is now given. Returning to activity 302, inspection data processing engine 202 may receive input data 220 comprising an inspection checklist is collected by one or more networked communication devices 130, such as, for example, a mobile handheld device. Embodiments of the inspection checklist are infrastructure asset dependent and may be generated by the infrastructure inspection system 110 to be specific to the industry and asset type. In an example wherein the infrastructure asset 140 comprises water storage tanks: the inspection checklist may be specific to, for example, flat bottom steel tanks, legged steel tanks, single pedestal steel tanks, and above- and below-ground concrete tanks. Each infrastructure asset 140 in each industry may comprise particular inspection parameters in a particular checklist to ensure the collection of necessary information for prioritization.

By way of a further example, data collected from one or more remote inspection devices 120 comprising one or more Remote Operated Vehicles (ROVs) also known as ‘unmanned underwater drones’ is interpreted and represented in the checklist. One or more ROVs provide for visual inspection and machine collection of data (for example, ultrasonic thickness readings of steel) to be fed into the checklist for analysis.

In other embodiments, one or more remote inspection devices 120 comprises one or more unmanned aerial vehicle (such as, for example, a drone) with one or more sensors 126 comprising, for example, Light Detection and Ranging (LiDAR), one or more cameras and/or visual processors providing for photogrammetry, and one or more GPS modules and processing engines providing for triangulation from the GPS. These capabilities provide for, for example, accurate collection of total measurement of the infrastructure assets 140, measurements of corroded steel or concrete, or failed structural aspects of the infrastructure asset. Data collected by one or more remote inspection devices 120 comprising an unmanned aerial vehicle comprises data focused on the entirety of the asset and provides for access to harder-to-reach areas of the structure of the one or more infrastructure assets 140. By way of further explanation, LiDAR data collected by the one or more remote inspection devices 120 provides for accurate calculation of the size of the infrastructure asset in square feet up to approximately 1 inch accuracy. Furthermore, one or more processing engines of infrastructure inspection system 110, remote inspection devices 120, and/or networked communication devices 130 provides for the three-dimensional geospatial representation from the LiDAR data to predict and visualize change detection. According to embodiments, visualization engine 208 receives one or more images or photographs and utilizes photogrammetry overlayed with the LiDAR data to determine the amount of corrosion present on one or more infrastructure assets 140. With both data fields, accurate (˜1 inch) measurements of corrosion are determined and used to feed prioritization matrix 222. Visualization engine 208 utilizes triangulation GPS data for the embedment of the data into a geospatial representation, which provides for a virtual walkaround of the asset in one or more remote networked locations remote from which the data is accessible. In addition, or as an alternative, embodiments of activity 302 contemplate input data 220 comprising data collected from imaging and spatial systems for interior areas, not submerged. Continuing with the example of method 300, at activity 304 calculation engine 204 generates prioritization matrix 222.

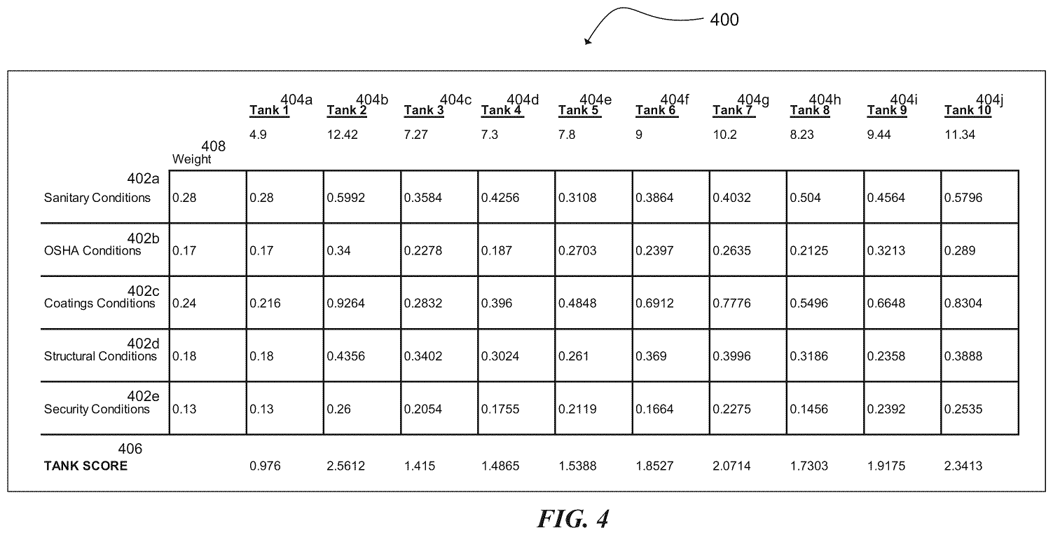

FIG. 4 illustrates exemplary infrastructure prioritization matrix 400, according to an embodiment. According to embodiments, infrastructure prioritization matrix 400 comprises prioritization subcategories 402a-402e for infrastructure assets 140 comprising ten tanks 404a-404j, which when solved generates infrastructure asset score 406 for the tanks 404a-404j. Although infrastructure prioritization matrix 400 is shown and described as comprising ten tanks 404a-404j the following prioritization subcategories: sanitary conditions 402a, OSHA conditions 402b, coatings conditions 402c, structural conditions 402d, and security conditions 402e, embodiments contemplate any size prioritization matrix 400 comprising any suitable number and type of infrastructure assets and prioritization subcategories, according to particular needs. For example, exemplary infrastructure prioritization matrix 400 may comprise other prioritization factors 224 assigned to various prioritization subcategories 402a-402e and other weights 408 according to other needs, such as, for example, infrastructure owners' priorities or the regulatory condition to maintain the particular infrastructure assets 140. In one embodiment, the weights for the prioritization matrix are based, at least in part, on the importance of the factors in the probability of failure (or rehabilitation need) by the asset owner. In addition, or as an alternative, the weights are further based, at least in part, on price, ease of repair, and any regulatory pressure to repair. According to embodiments, infrastructure inspection system 110 adjusts weights over time using the collected and/or historical data to assign an importance to a role their associated factor plays in failure, or not. In some embodiments, weighted factors are dependent of the regulatory requirements or asset owner needs, not the assets' condition. Measurements of these factors collected during inspection determine the score for a particular asset, according to Equation 1, as disclosed below. The compilation of scores from many infrastructure assets and weights makes up the total asset probability of failure. Once scored by calculation engine 204, prioritization engine 206 performs a statistical analysis on all like assets, such as, for example, generating a bell curve based on the calculated mean and standard deviation.

According to embodiments, infrastructure asset score 406 is calculated according to Equation 1.

$$P = W \times R \qquad ( 1 )$$

wherein, infrastructure asset score 406 (P) is equal to weight 408 (W) multiplied by the input (R), represented in the prioritization matrix 400 by the intersection of each prioritization factor 402a-402e and tank 404a-404j. According to embodiments, weight 408 for each cross-section of data collected must be equal to one. In addition, or as an alternative, weight 408 is derived from the analysis of survey data collected by asset owners and industry professionals to rank the importance of each factor in their decision to rehabilitate infrastructure assets 140. The input (R) comprises input data 220 collected during the inspection process from the multiple sources available, such as, for example, one or more remote inspection devices 120 and networked communication devices 130. Infrastructure asset score 406 comprises the score to be analyzed against the other similar asset types and comprising the sum of all weighted factors.

According to some embodiments, infrastructure assets 140 comprise two or more different subcategories of factors. Calculation engine 204 may generate prioritization matrix 222 with weights, inputs, and scores for all subcategories, which it the combines into categorical scores. When assets have multiple categories, calculation engine 204 weighs each category one or more additional times to achieve overall scores. Returning to the example of method 300, at activity 308, prioritization engine 206 determines a rehabilitation priority for each of the assessed infrastructure assets 140, as disclosed above. According to an embodiments, prioritization engine 206 generates a bell curve of asset based on the severity and likelihood of failure based, at least in part, on the overall output from prioritization matrix 222.

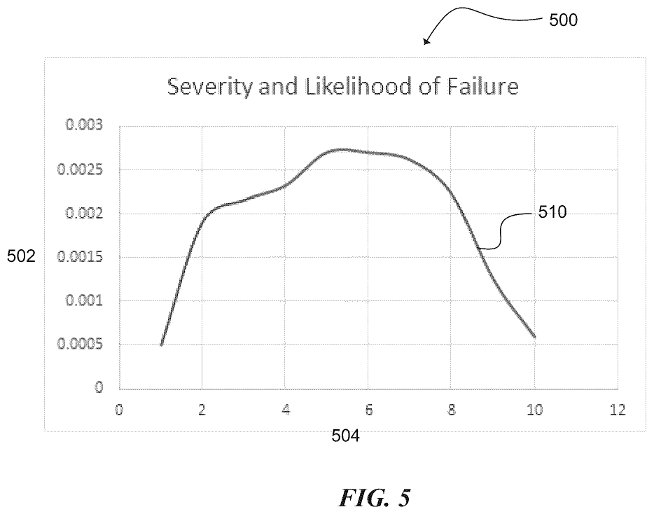

FIG. 5 illustrates severity and likelihood of failure chart 500, according to an embodiment. Severity and likelihood of failure chart 500 comprises scores 502 plotted against the quantity of assets. According to embodiments, severity and likelihood of failure chart 500 generates a bell curve that provides for an analysis of the inspected infrastructure asset compared with other like assets scored to generate a probable zone for rehabilitation. In some embodiments, assets less than one standard deviation below the mean are in the probable zone for rehabilitation, which indicates that those infrastructure assets 140 scored the lowest based on the weighted factors.

In addition to the exemplary severity and likelihood of failure chart 500, prioritization engine 206 determines standard deviations from the mean infrastructure asset score for the scored infrastructure assets and assigns a rehabilitation priority. According to embodiments, prioritization engine 206 assigns an infrastructure asset 140 (such as, for example, a tank of the one or more tanks 404a-404j of FIG. 4) that scores lower than one standard deviation from the mean as needing rehabilitation. As more infrastructure assets 140 are evaluated, other infrastructure assets 140, such as the one or more tanks 404a-404j, in need of rehabilitation will be moved in and out of the zone of probable rehabilitation.

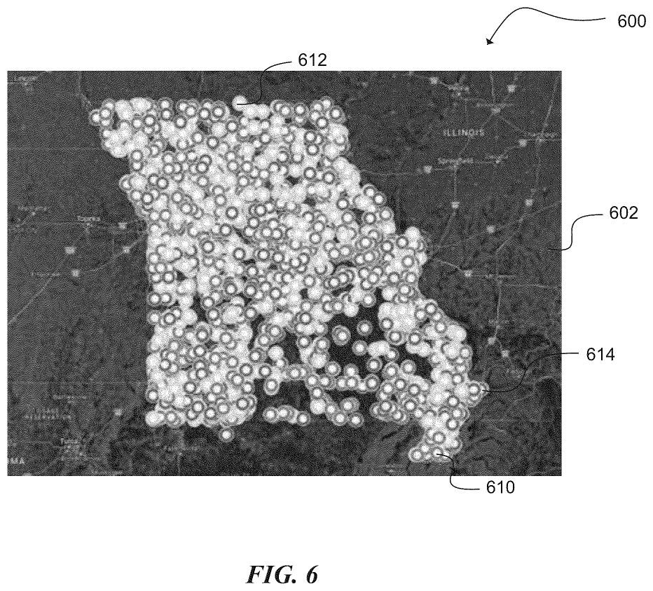

Continuing with the example describing an embodiment of method 300, at activity 310, visualization engine 208 generates a geospatial representation of infrastructure assets 140, as disclosed above. According to embodiments, visualization engine 208 generates exemplary geospatial representation 600 of FIG. 6.

FIG. 6 illustrates exemplary geospatial representation 600, according to an embodiment. Exemplary geospatial representation 600 comprises regional map 602 and infrastructure asset icons 610-614. In one embodiment, visualization engine 208 illustrates infrastructure assets 140 using infrastructure asset icons 610-614 comprising a color, shading, or other graphic element that indicates the rehabilitation priority of the represented infrastructure asset. By way of example only and not by way of limitation, an high priority icon 610 represents an infrastructure asset that is scored less than one standard deviation less than the mean (such as for example, using a red icon), a neutral or medium rehabilitation priority icon 612 represents an infrastructure asset within one standard deviation less than or greater than the mean (such as, for example, using a yellow icon), and a low rehabilitation priority icon 614 represents an asset above one standard deviation from the mean (such as, for example, using a green icon). Although infrastructure asset icons 610-614 are shown and described using particular colors and shapes, embodiments contemplate any suitable color, icon, graphic, shading, or the like to represent any suitable categorization of rehabilitation priority, according to particular needs.

In addition, or as an alternative, visualization engine 208 generates geospatial data visualization using the location of each asset along with the triangulated GPS overlay of the LiDAR and Photogrammetry imaging. As part of each infrastructure asset, general details about the assets are completed in the metadata within the analysis, such as, for example, the entire square footage of the assets along with the percentage of corrosion, size, owner's information, etc. Each infrastructure asset will have embedded triangulated imagery from LiDAR and Photogrammetry to provide for a three-dimensional walk around of that asset.

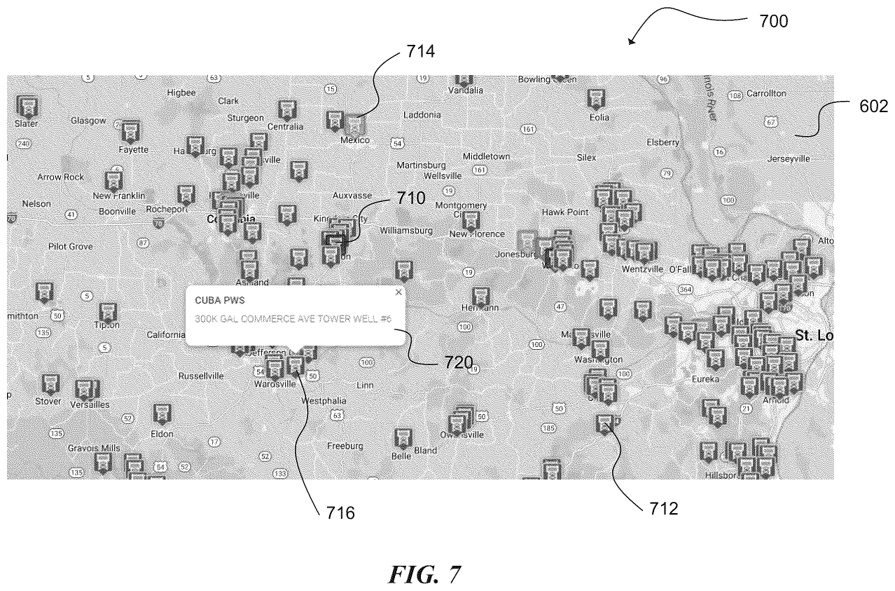

FIG. 7 illustrates exemplary geospatial representation 700, according to a further embodiment. Similar to the previous example, exemplary geospatial representation 700 comprises regional map 602. Infrastructure asset icons 710-716 similarly represent one or more infrastructure assets 140. In one embodiment, visualization engine 208 illustrates infrastructure assets 140 using infrastructure asset icons 710-714 comprising a color, shading, or other graphic element that indicates the rehabilitation priority of the represented infrastructure asset. In this example, a high priority icon 710 represents an infrastructure asset that is scored less than one standard deviation less than the mean (such as for example, using a red icon), a medium rehabilitation priority icon 712 represents an infrastructure asset within one standard deviation less than or greater than the mean (such as, for example, using an orange icon), and a neutral rehabilitation priority icon 714 represents an asset above one standard deviation from the mean (such as, for example, using a grey icon). Although infrastructure asset icons 710-714 are shown and described using particular colors and shapes, embodiments contemplate any suitable color, icon, graphic, shading, or the like to represent any suitable categorization of rehabilitation priority, including, for example, having one or more intermediate colored icons that represent other levels of priority equal to other rankings of scores, according to particular needs. Continuing with the illustrated example, selection of an icon may display additional information regarding the infrastructure asset represented by the icon. For example, in response to selection of a particular icon, selected icon 716, visualization engine 208 generates a window 720 on the graphical user interface displaying additional information regarding the selected asset, such as, for example, the location of the asset, the current state of the asset, the type of maintenance or rehabilitation that is needed, the size, volume, or other measurement of the asset, the type of asset, and the like.

Reference in the foregoing specification to “one embodiment”, “an embodiment”, or “some embodiments” means that a particular feature, structure, or characteristic described in connection with the embodiment is included in at least one embodiment of the invention. The appearances of the phrase “in one embodiment” in various places in the specification are not necessarily all referring to the same embodiment.

While the exemplary embodiments have been shown and described, it will be understood that various changes and modifications to the foregoing embodiments may become apparent to those skilled in the art without departing from the spirit and scope of the present invention.

1. A system, comprising:
one or more remote inspection devices comprising one or more processors, memory, and sensors configured to conduct remote inspection of an infrastructure asset;
an infrastructure inspection system, comprising a server comprising an inspection data processing engine, a calculation engine, a prioritization engine, and a visualization engine, the infrastructure inspection system configured to prioritize rehabilitation of the infrastructure asset by:
receiving, by the inspection data processing engine, input from the one or more remote inspection devices;
generating, by the calculation engine, a prioritization matrix;
solving, by the calculation engine, the prioritization matrix;
determining, by the prioritization engine, a rehabilitation priority of the infrastructure asset; and
generating, by the visualization engine, a geospatial representation of the infrastructure asset.

2. The system of claim 1, wherein the visualization engine generates the geospatial representation of the infrastructure asset by mapping the rehabilitation priority of the infrastructure asset.

3. The system of claim 1, wherein the infrastructure inspection system is further configured to:
generate, by the prioritization engine, a machine learning model trained on historical input data and rehabilitation priority data.

4. The system of claim 1, wherein the infrastructure inspection system is further configured to:
generate, by the visualization engine, a visualization using triangulated imagery from LiDAR and photogrammetry that provides for a virtual three-dimensional walkaround of the infrastructure asset.

5. The system of claim 1, wherein the prioritization engine determines the rehabilitation priority of the infrastructure asset by statistical analysis using a bell curve and calculating the quantity of standard deviations an infrastructure asset score is from a mean of scores of other infrastructure assets.

6. The system of claim 1, wherein the one or more remote inspection devices conduct a remote inspection of a first and a second infrastructure asset.

7. The system of claim 6, wherein the visualization engine generates the geospatial representation of the first and second infrastructure assets by mapping the rehabilitation priorities of the first and second infrastructure assets and displays a graphical display indicating the difference in priority between the first and second infrastructure assets.

8. A method, comprising:
remotely inspecting, by one or more remote inspection devices comprising one or more processors, memory, and sensors, an infrastructure asset;
prioritizing rehabilitation of the infrastructure asset, by an infrastructure inspection system, comprising a server comprising an inspection data processing engine, a calculation engine, a prioritization engine, and a visualization engine, wherein prioritizing rehabilitation of the infrastructure asset comprises:
receiving, by the inspection data processing engine, input from the one or more remote inspection devices;
generating, by the calculation engine, a prioritization matrix;
solving, by the calculation engine, the prioritization matrix;
determining, by the prioritization engine, a rehabilitation priority of the infrastructure asset; and
generating, by the visualization engine, a geospatial representation of the infrastructure asset.

9. The method of claim 8, wherein the visualization engine generates the geospatial representation of the infrastructure asset by mapping the rehabilitation priority of the infrastructure asset.

10. The method of claim 8, wherein prioritizing rehabilitation of the infrastructure asset further comprises:
generating, by the prioritization engine, a machine learning model trained on historical input data and rehabilitation priority data.

11. The method of claim 8, wherein prioritizing rehabilitation of the infrastructure asset further comprises:
generating, by the visualization engine, a visualization using triangulated imagery from LiDAR and photogrammetry that provides for a virtual three-dimensional walkaround of the infrastructure asset.

12. The method of claim 8, wherein determining the rehabilitation priority of the infrastructure asset comprises statistical analysis using a bell curve and calculating the quantity of standard deviations an infrastructure asset score is from a mean of scores of other infrastructure assets.

13. The method of claim 8, wherein the one or more remote inspection devices conduct a remote inspection of a first and a second infrastructure asset.

14. The method of claim 13, wherein prioritizing rehabilitation of the infrastructure asset further comprises:
generating, by the visualization engine, the geospatial representation of the first and second infrastructure assets by mapping the rehabilitation priorities of the first and second infrastructure assets; and
displaying, by the visualization engine, a graphical display indicating the difference in priority between the first and second infrastructure assets.

15. A non-transitory computer-readable medium embodied with software, the software when executed:
receives inspection data of an infrastructure asset from one or more remote inspection devices comprising one or more processors, memory, and sensors;
prioritizes rehabilitation of the infrastructure asset, by an infrastructure inspection system, comprising a server comprising an inspection data processing engine, a calculation engine, a prioritization engine, and a visualization engine, by:
receiving, by the inspection data processing engine, input from the one or more remote inspection devices;
generating, by the calculation engine, a prioritization matrix;
solving, by the calculation engine, the prioritization matrix;
determining, by the prioritization engine, a rehabilitation priority of the infrastructure asset; and
generating, by the visualization engine, a geospatial representation of the infrastructure asset.

16. The non-transitory computer-readable medium of claim 15, wherein the visualization engine generates the geospatial representation of the infrastructure asset by mapping the rehabilitation priority of the infrastructure asset.

17. The non-transitory computer-readable medium of claim 15, wherein the software when executed prioritizes rehabilitation of the infrastructure asset by further:
generating, by the prioritization engine, a machine learning model trained on historical input data and rehabilitation priority data.

18. The non-transitory computer-readable medium of claim 15, wherein the software when executed prioritizes rehabilitation of the infrastructure asset by further:
generating, by the visualization engine, a visualization using triangulated imagery from LiDAR and photogrammetry that provides for a virtual three-dimensional walkaround of the infrastructure asset.

19. The non-transitory computer-readable medium of claim 15, wherein determining the rehabilitation priority of the infrastructure asset comprises statistical analysis using a bell curve and calculating the quantity of standard deviations an infrastructure asset score is from a mean of scores of other infrastructure assets.

20. The non-transitory computer-readable medium of claim 15, wherein the software when executed:
receives inspection data from one or more remote inspection devices of at least two infrastructure assets.
